(19) United States
(12) Patent Application Publication
(10) Pub. No.: US 2007/0267174 A1
(43) Pub. Date: Nov. 22, 2007

(54) Heat sink of plasma display apparatus

(75) Inventor: Bog Ryong Kim, Gumi-si (KR)

Correspondence Address: BIRCH STEWART KOLASCH & BIRCH, PO BOX 747, FALLS CHURCH, VA, 22040-0747, US

(73) Assignee: LG Electronics Inc.

(21) Appl. No.: 11/540,710

(22) Filed: Oct. 2, 2006

(30) Foreign Application Priority Data
May 18, 2006 (KR) 2006-44866

(51) Int. Cl. H05K 7/20

(52) U.S. Cl. 165/80.3; 165/185; 361/704

(57) ABSTRACT

As to a heat sink manufacturing method of a plasma display apparatus according to the present invention and the manufacturing device, a widthwise direction air channel and a lengthwise direction air channel are formed through a extrusion and a rolling processing to facilitate a processing with a continuous extrusion and rolling processing. Accordingly, the productivity is notably improved.

This application claims the benefit of Korean Patent Application No. 10-2006-0044866 filed on May 18, 2006, which is hereby incorporated by reference for all purposes as if fully set forth herein.

### BACKGROUND OF THE INVENTION

1. Field of the Invention

The present invention relates to the heat sink of a plasma display apparatus, in particular, to the heat sink of the plasma display apparatus having a low cost and a simple process through being manufactured with a extruding processing and a rolling processing.

2. Description of the Background Art

The plasma display apparatus PDP is a flat panel display apparatus which displays an image by using a plasma discharge, being used as a high definition television, a monitor, and an indoor/outdoor display for advertisement because it suitable for big screen with a fast response speed.

FIG. 1 is a perspective drawing in which a conventional heat sink of a plasma display apparatus is illustrated.

The conventional heat sink is comprised of a heat sink base 1 adhering to the heat-resisting part of the plasma display apparatus, and a cooling plate 2 assembled with the heat sink base 1 to emit the heat to the air.

The heat sink base 1 is implemented in the widthwise of the plasma display apparatus in a long queue, while the cooling plate 2 is implemented in the lenghtwise of the plasma display apparatus.

In the cooling plate 2, a cooling pin 3 is formed into an upward/downward so that the heat transmitted from the heat sink base 1 may be convected to the upper, while the formation direction of the cooling pin 3 is formed is orthognal with the formation direction of the heat sink base 1.

Further, the heat sink base 1 and the cooling plate 2 are manufactured by the extrusion method for the saving of the cost.

So, the heat sink base 1 is formed to the lengthwise directionwith a shape bended in a long queue, with being extruded, while the cooling plate 2 is formed to the direction in which the cooling pin 3 is formed in a long queue, with being extruded.

In the heat sink base 1 and the cooling plate 2, an additional connecting member 5 is connected to be assembled, while a joint hole 4 is processed for the assembly of the connecting member 5 in the heat sink base 1 and the cooling plate 2.

As to the heat sink of the plasma display apparatus manufactured as described above, the heat sink base 1 and the cooling plate 2 are manufactured by extruding. However, there is a problem that the manufacturing time and the operation procedure is troublesome because each component is combined through an additional assembly process.

Furthermore, the conventional heat sink has an additional process for processing the joint hole in the assembly process of the heat sink base 1 and the cooling plate 2. Therefore, there is a problem in that the manufacturing process is complicated. In addition, for this, the operation procedure of an operator is generated with large amount.

### SUMMARY OF THE INVENTION

Accordingly, an object of the present invention is to solve at least the problems and disadvantages of the background art.

The objective of the present invention is to provide a heat sink of a plasma display apparatus and manufacturing method of the same, wherein the manufacturing process of which is simple through an extruding process.

Further, another objective of the present invention is to provide a heat sink of the plasma display apparatus for forming an air channel into the different direction of the extruded direction.

Further, another object of the present invention is to provide a heat sink of the plasma display apparatus and manufacturing method of the same, which is capable of preventing from being twisted or bended when it is extruded.

A heat sink and a plasma display apparatus including the heat sink according to the present invention comprises a plurality of radiators formed to be protruded through an extrusion by an extrusion die and a rolling processing pressurized by a star roller; and a plate part in which a widthwise direction air channel and a lengthwise direction air channel are formed by the plurality of protruded radiators.

In accordance with the present invention, the heat sink and the plasma display apparatus further comprises a bent portion protruded to the opposite direction to the protrusion direction of the radiator in the plate part.

In accordance with the present invention, the heat sink and the plasma display apparatus further comprises a plateau formed flat between the bent portion and the radiator interval in the plate part.

In accordance with the present invention, the bent portion is formed in the both side ends of the plate part respectively.

The heat sink is manufactured as a pair heat sink form in which a pair is combined, while the pair heat sink is cut and separated to at least one of the widthwise direction and the lengthwise direction.

The heat sink is formed to at least one of the widthwise direction and the lengthwise direction to be symmetrical.

The heat sink is manufactured as a pair heat sink form in which a pair is combined, while the pair heat sink is cut and separated to at least one of the widthwise direction and the lengthwise direction.

In accordance with the present invention, the heat sink and the plasma display apparatus further comprises a heat transfer member installation unit in which the heat transfer member is settled with a hollow type in the opposite surface in which the radiator is formed in the plate part.

In the widthwise direction air channel and the lengthwise direction air channel of the heat sink, one is formed by the extrusion, while the other is formed by the rolling processing.

In the plate part, the bent portion and the radiator include a plateau formed flat, while the heat transfer member installation unit is formed in the opposite surface of the plateau.

In the widthwise direction air channel and the lengthwise direction air channel of the heat sink, one is formed by the extrusion, while the other is formed by the rolling processing.

The widthwise direction air channel and the lengthwise direction air channel form a platform where a height is different.

The widthwise direction air channel and the lengthwise direction air channel form a platform where a height is different, while the platform is formed to be inclined.

The widthwise direction air channel and the lengthwise direction air channel form a platform where a height is different, while the platform is formed to be curved surface.

As described in the above, as to the heat sink of the plasma display apparatus according to the present invention and manufacturing method of the same, there is an effect that a processing is facilitated because the widthwise air channel and the lengthwise air channel are formed with a extruding processing and a rolling processing. In addition, as the extruding processing and the rolling processing are consecutively performed, the productivity is much more improved in comparision with a conventional method.

Further, as to the heat sink of the plasma display apparatus according to the present invention and manufacturing method of the same, there is an effect that the cost of manufacture the extrusion die is much more inexpensive in comparision with a diecasting or the other press processing because the heat sink is processed through the extruding by the extrusion die. In addition, the damage of the extrusion die in manufacturing is remarkably less to implement a high durability.

Further, as to the heat sink of the plasma display apparatus according to the present invention, bending or transforming into one side is prevented in the extrusion die when being extruded because the both ends of the heat sink are manufactured as a pair heat sink form in which the both ends of the heat sink are symmetrical.

### BRIEF DESCRIPTION OF THE DRAWINGS

The invention will be described in detail with reference to the following drawings in which like numerals refer to like elements. The accompany drawings, which are included to provide a further understanding of the invention and are incorporated in and constitute a part of this specification, illustrate embodiments of the invention and together with the description serve to explain the principles of the invention. In the drawings:

FIG. 1 is a perspective drawing in which a conventional heat sink of a plasma display apparatus is illustrated.

FIG. 2 is a perspective drawing in which a plasma display apparatus according to the present invention is partly cut out to be illustrated.

FIG. 3 is a rear elevation in which the module of a plasma display apparatus according to the present invention is illustrated.

FIG. 4 is a perspective drawing in which a pair heat sink manufactured by a heat sink manufacturing apparatus according to the present invention is illustrated.

FIG. 5 is a perspective drawing in which a heat sink according to the present invention is illustrated.

FIG. 6 is a schematic perspective view in which a heat sink manufacturing apparatus according to the present invention is illustrated.

FIG. 7 is a schematic side view in which a heat sink manufacturing apparatus according to the present invention is illustrated.

FIG. 8 is a cross-sectional view in which in a star roller and a pair heat sink of a heat sink manufacturing apparatus according to the present invention is illustrated.

FIG. 9 is a front view in which an extrusion die of a heat sink manufacturing apparatus according to the present invention is illustrated.

FIG. 10 is an enlargement of a pair heat sink in which a lengthwise flow channel is formed by a star roller according to the present invention.

FIG. 11 is a flow chart where the manufacturing method of a heat sink according to the present invention is illustrated.

FIG. 12 is a side view in which a heat sink manufacturing apparatus according to a second embodiment of the present invention is illustrated.

FIG. 13 is a perspective drawing in which the internal fabric of a plasma display panel according to the present invention is illustrated.

FIG. 14 is a plane in which an electrode arrangement of the panel according to the present invention is illustrated.

FIG. 15 is a timing diagram in which a plurality of subfields comprising one frame according to the present invention is time-divided.

FIG. 16 is a timing diagram in which driving signals for panel driving according to the present invention is illustrated.

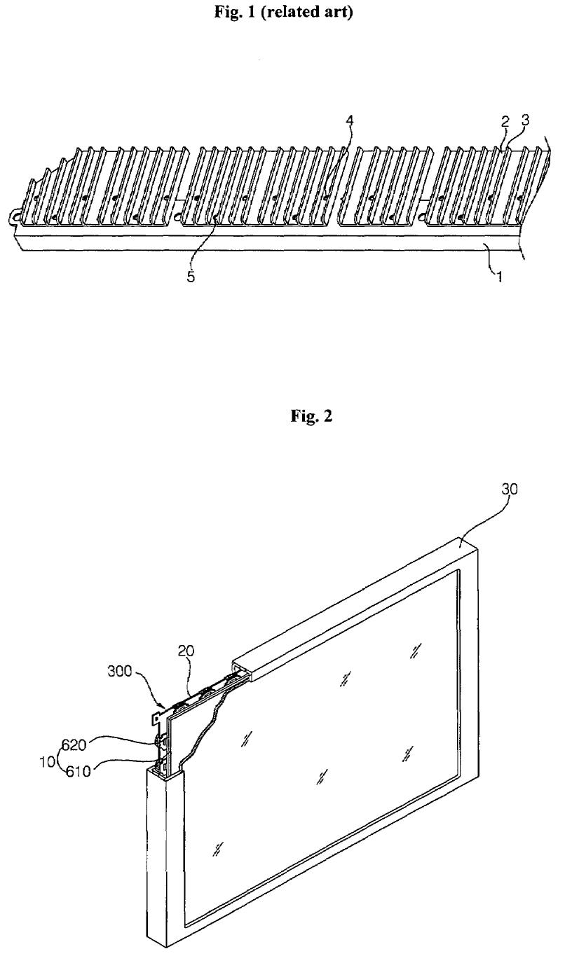

### DETAILED DESCRIPTION OF PREFERRED EMBODIMENTS

Preferred embodiments of the present invention will be described in a more detailed manner with reference to the drawings. Reference will now be made in detail to embodiments of the present invention, examples of which are illustrated in the accompanying drawings.

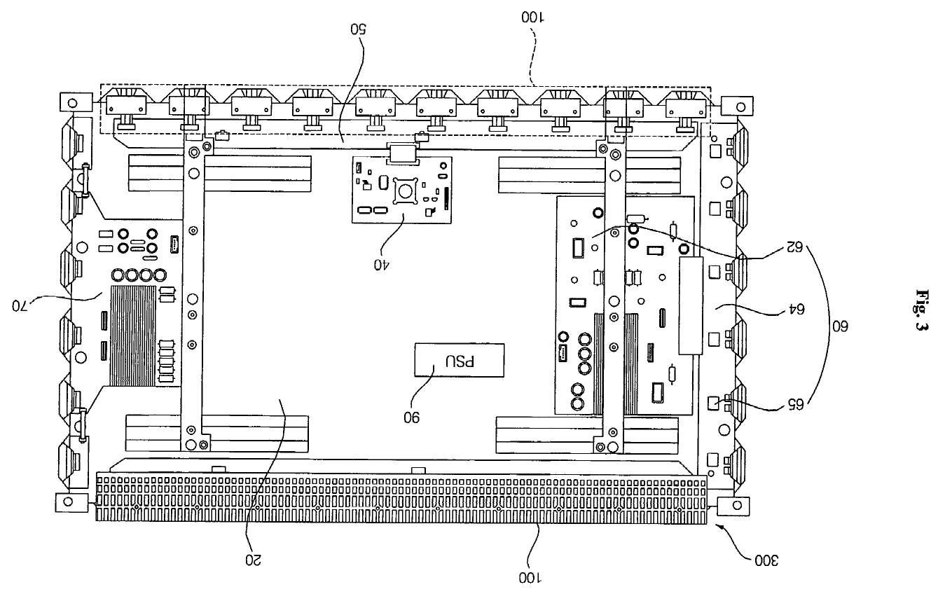

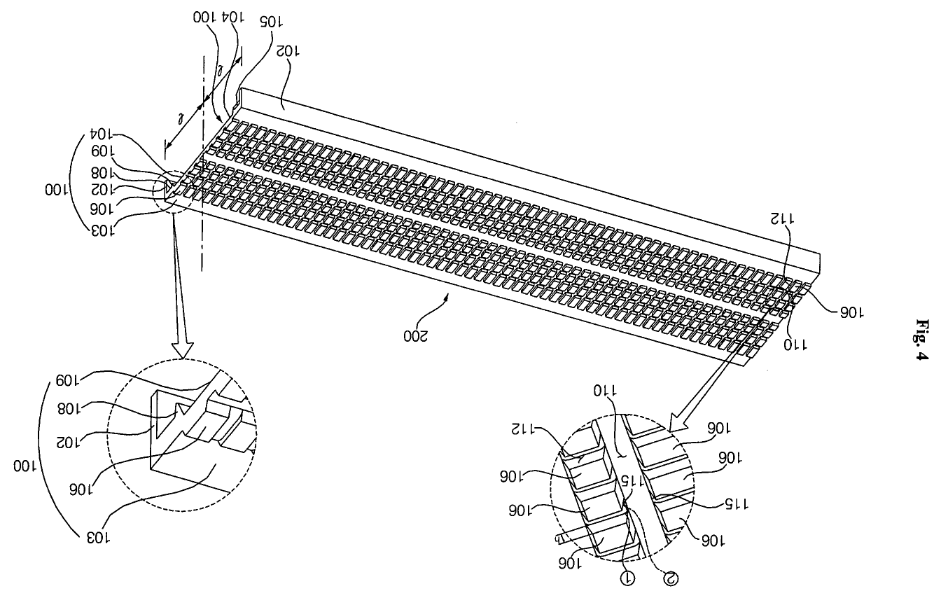

FIG. 2 is a perspective drawing in which a plasma display apparatus according to the present invention is partly cut out to be illustrated. FIG. 3 is a rear elevation in which the module of a plasma display apparatus according to the present invention is illustrated.

As shown in FIG. 2, FIG. 3, the plasma display apparatus PDP according to the present invention is comprised of a panel 10 coalesced with an upper plate and a lower plate, an inert mixing gas is filled in an inside of which to emit the visible ray by the electronics which are spouted out when a current is applied, a cooling fin 20 adhered to the rear side of the panel 10, a driving board 40 implemented in the rear side of the cooling fin 20 and a case 30 covering the edge of the panel 10 and the cooling fin 20.

The panel 10 is comprised of a front substrate 610 which is exposed to a user, a rear substrate 620 which is arranged behind of the front substrate 610 and is coalesced to the front substrate and an inert mixing gas filled in the inside of the front/rear substrate 610/620.

Inside of the panel 10, there are a plurality of scan electrodes (not shown), a plurality of address electrodes (not shown) intersecting with the scan electrodes, and a fluorescent substance(not shown), coated onto inside of the panel 10, generating the visible ray by discharge in case the current between the scan electrodes and the address electrodes is applied.

Particularly, the PDP comprises a module 300 including the panel 10, the cooling fin 20, and the driving board 40, while the case 30 is installed in order to cover the outer side of the module 300.

The cooling fin 20 is installed at the rear side of the panel 10 to support the panel 10, absorbing the heat generated in the panel 10 to release.

In the rear side of the cooling fin 20, the driving board 40 applying a current to the panel 10 is installed.

The driving board 40 is comprised of a data drive board 50 applying a current to the address electrode (not shown) of the panel 10, a scan board 60 applying a current to the scan electrode (not shown) of the panel 10, a sustain board 70 applying a current in the sustain electrode(not shown) of the panel 10, a main controller 80 which controls the scan board 60 and the sustain board 70, and a power supplier 90 supplying the power to each board 50, 60, 70, 80.

The data drive board 50 applies a current to the address electrode formed in the panel 10 to select only the discharge cell discharged among a plurality of discharge cells (not shown) formed in the panel 10.

The data drive board 50 is installed in one of or in both of the upper side or the bottom side of the panel 10 according to a single scan method or a dual scan method. In the present embodiment, it is installed in both of the upper side and the bottom side of the panel 10 since the panel 10 is used with the dual scan method.

Moreover, the data drive board 50 is connected to the main controller 80 to apply a data signal to the address electrode.

In this case, data integrated circuit (not shown) is installed in the data drive board 50 in order to control the current applied to the address electrode, while, in the data integrated circuit, a switching is generated to control the current applied and a large amount of heat is generated.

So, in data drive board 50, a heat sink 100 is installed in order to appease the generation of heat generated in the control process.

As shown in FIG. 2, the scan board 60 is comprised of a scan sustain board 62 connected to the main controller 80, and a scan driver board 64 connecting the scan sustain board 62 to the panel 10.

In the embodiment, the scan driver board 64 is divided into 2 part of upper/lower part to be installed, while it may be installed in a singular number or in a multiple number.

In the scan driver board 64, a scan IC 65 applying a current to the scan electrode of the panel 10 is installed, while the scan IC 65 consecutively applies the waveform of a reset, a scan, and a sustain step to the scan electrode.

The power supplier 90 supplies the voltage that the PSU power supply unit does not provide to each board 50, 60, 70, 80.

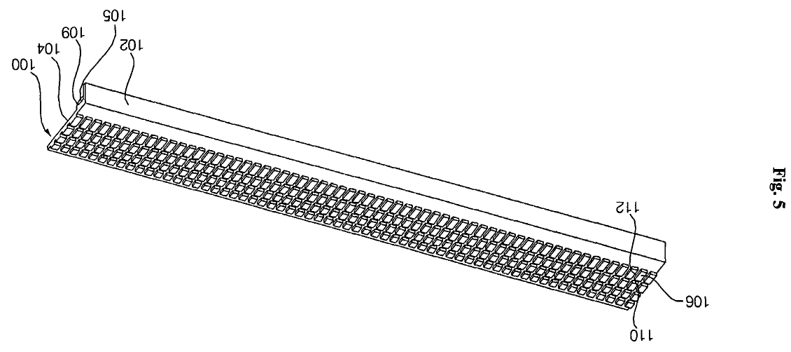

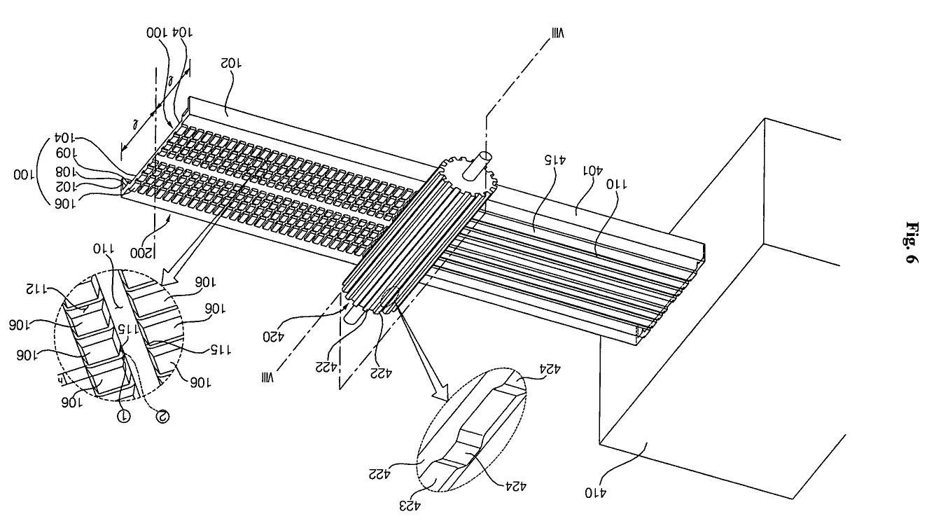

FIG. 4 is a perspective drawing in which a pair heat sink manufactured by a heat sink manufacturing apparatus according to the present invention is illustrated, FIG. 5 is a perspective drawing in which a heat sink according to the present invention is illustrated.

As shown in FIG. 4, FIG. 5, the heat sink 100 according to the present invention, after being manufactured as a pair heat sink 200 consisting of pair, it is divided into two to be used.

The heat sink 100 uses a aluminium material as the thermal conductivity of which is high and the extrusion of which is facilitated, The heat sink 100 is comprised of a bent portion 102 covering the edge of the module 300, and a plate part 104 adhering closely to the heat generating part of the module 300, while a plurality of radiators 106 are protruded on the plate part 104.

The radiator 106 is protruded with a rectangular type. The concavo-convex radiator 106 and air are heat-exchanged, while the heat-exchanged air is convected to move.

The radiator 106 is arranged to the lengthwise directionand the widthwise directionof the plate part 104. Due to the arrangement of the radiator 106, the widthwise direction air channel 110 and the lengthwise direction air channel 112 where the heated air flows is formed.

The widthwise direction air channel 110 is formed into the same direction as the longitudinal direction of the heat sink 100 in a long queue. The lengthwise direction air channel 112 is formed to be crossed with the widthwise direction air channel 110, being arranged into the upward/downward in the installation of the module 300. The widthwise direction air channel 110 and the lengthwise direction air channel 112 are formed as a shape of the recess formed between the radiators 106.

The upward/downward length of the radiator 106 installed in the lowest part among a plurality of radiators 106 is most long, the length of which becomes shorter in the upper part to facilitate the mixing and movement of the convected air.

In the meantime, the heat transfer member installation unit 108 in which the graphite is adhered is formed in the bottom surface of the heat sink 100, or the reverse surface of the radiator 106 so that the heat transmission may be efficiently performed.

The heat transfer member installation unit 108 is formed in the lengthwise direction of the heat sink 100 in a long queue. In order that the graphite which is the heat transfer member 105 is adhered in a stable, the protrusion 109 is formed to surround the heat transfer member 105.

Further, on the reverse surface of the heat transfer member installation unit 108 in the plate part 104, the plateau 103 in which the designated even area is formed is formed into the widthwise direction.

In the plateau 103, a joint hole(not shown) is formed through an additional process, being fixed to the cooling fin 20 of the plasma display apparatus through the joint hole.

So, the plateau 103 is formed between the bent portion 102 and the radiator 106.

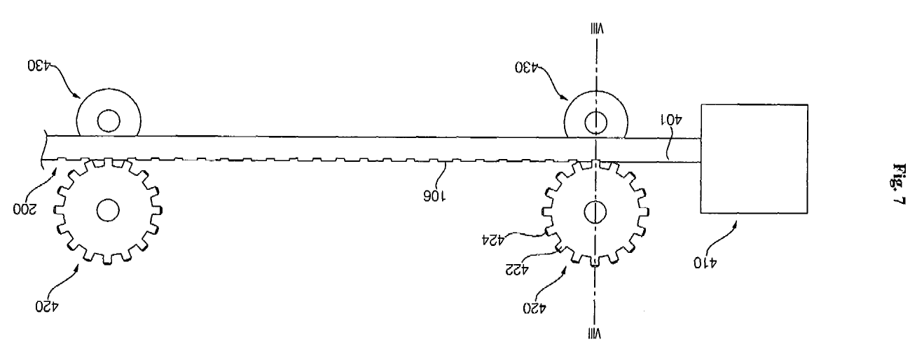

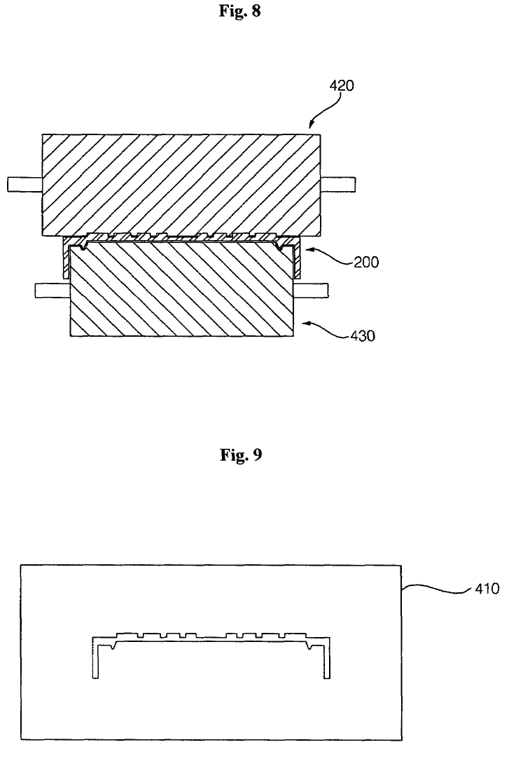

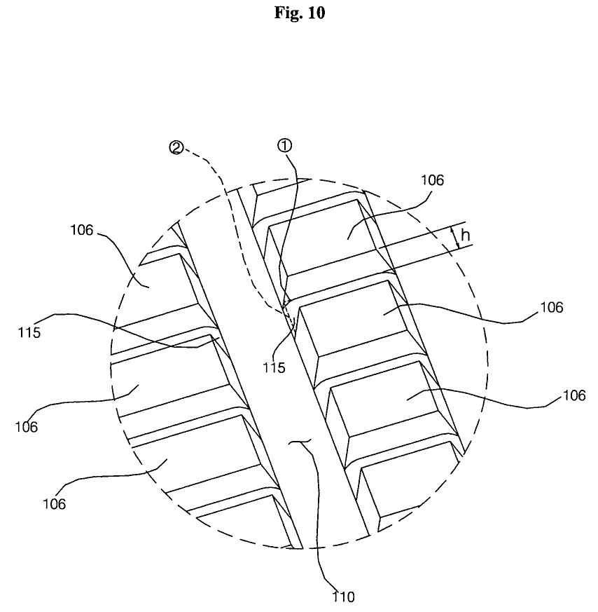

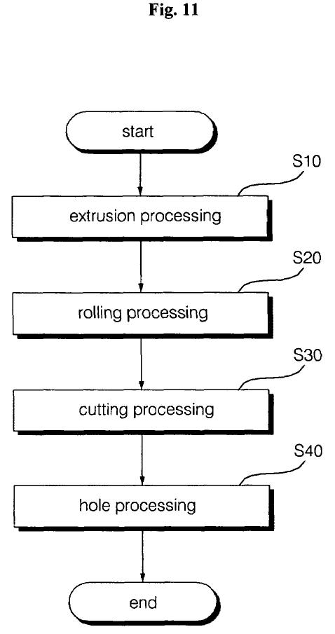

FIG. 6 is a schematic perspective view in which a heat sink manufacturing apparatus according to the present invention is illustrated, FIG. 7 is a schematic side view in which a heat sink manufacturing apparatus according to the present invention is illustrated, FIG. 8 is a cross-sectional view in which in a star roller and a pair heat sink of a heat sink manufacturing apparatus according to the present invention is illustrated, FIG. 9 is a front view in which an extrusion die of a heat sink manufacturing apparatus according to the present invention is illustrated, FIG. 10 is an enlargement of a pair heat sink in which a lengthwise flow channel is formed by a star roller according to the present invention.

The heat sink manufacturing apparatus according to the present invention is comprised of a extrusion die 410 which extrudes a fused metal to makes a extruded product 401 in which the widthwise direction air channel 110 is formed, a star roller 420 pressurizing the extruded product 410 extruded in the extrusion die 410 to forms the lengthwise direction air channel 112, and a support roller 430 which is located in the opposite side of the star roller 420 based on the extruded product 401 to support the load applied from the star roller 420.

The extrusion die 410 extrudes the heated metal to process the extruded product 401 so that the widthwise direction air channel 110 may be formed. The extruded product 401 extruded through the extrusion die 410 is processed in the form of the pair heat sink 200 in which the bent portion 102 is formed in the both side end.

As described in the above, if the extruded product 401 is made in the form of the pair heat sink 200, it is prevented that the extruded product 401 ejected through the extrusion die 410 is transformed or bended into one side since a rubbing and a pressure applied to the extruded product 401 becomes a symmetry.

So, the pushers of the extrusion die 410 is formed to be symmetrical in the both side end so that the bent portion 102 is formed to be symmetrical from the push-out direction center of the pair heat sink.

Particularly, as to the heat sink 100 according to the present invention, the bent portion 102 is formed in only one side. Thus, if the extrusion die 410 is manufactured in the heat sink 100 form, the extruded product 401 is bent and transformed to the side where the rubbing is less although extrusion is performed to a metal with a proper pressure.

So, in the embodiment, the extrusion die 410 is made so that the both sides of the extruded product 401 be symmetrical and the heat sink 100 is produced as the pair heat sink 200 form.

In the meantime, if the extruded product 401 is ejected through the extrusion die 410, in the extruded product 401, a plurality of barrier 415 which form a plurality of widthwise direction air channels 110 side by side into the direction in which the extruded product 401 is ejected are formed in the widthwise direction.

So, the widthwise direction air channel 110 is formed between the barriers 415, while the barrier 415 is shaped to the radiator 106 by the following tooth form 422.

In the bottom surface of the extruded product 401, the heat transfer member installation unit 108 and the protrusion 109 are shaped at the same time.

The star roller is formed into a cylindrical, while the star roller 420 forms the lengthwise direction air channel 112 in the barrier 415 of the extruded product 401. A plurality of tooth form 422 are formed with a radial in the outer circumference from the center of axis.

The tooth form 422 pressurizes the surface of the barrier 415 of the extruded product 401 to form the lengthwise direction air channel 112. In the embodiment, the tooth form 422 is formed to be orthognal with the widthwise direction air channel 110, formed into an axial in a long queue on the circumference of the star roller 420.

Although not illustrated in the embodiment, the lengthwise direction air channel 112 may be formed to cross the widthwise direction air channel 110 not to be orthogonal as the lengthwise direction air channel 112 is formed to connect the widthwise direction air channel 110.

In addition, in the outer end 423 of the tooth form 422, an addition tooth form 424 which is inserted into the widthwise direction air channel 110 and pressurizes the bottom of the barrier 415 is formed. The addition tooth form 424 is much protruded to the outer side of the tooth form 422.

That is, the addition tooth form 424 is much protruded to the radial of the star roller 420. When the extruded product 401 and the tooth form 422 are compressed, the addition tooth form 424 stronly pressurizes the root portion of the barrier 415 to minimize the difference of the widthwise direction air channel 110 and the lengthwise direction air channel 112.

The widthwise direction air channel 110 is formed in the extrusion process, while the lengthwise direction air channel 112 is formed by the compression of the star roller 420. Thus, it is substantially difficult to form the widthwise direction air channel 110 and the lengthwise direction air channel 112 with the same height though the pressure of the star roller 420 is sufficient.

Accordingly, the tooth form 422 stronly compresses the platform 115 between the widthwise direction air channel 110 and the lengthwise direction air channel 112 so that the height difference be smoothly formed.

As shown in FIG. 10, if the barrier 415 is processed by the tooth form 422 of the star roller 420 according to the present invention, the lengthwise direction air channel 112 is formed with the height difference of h.

In this case, the platform 115 is formed as the dotted line \hat{1} form when the tooth form 422 pressurizes the barrier 415.

But if the addition tooth form 424 pressurizes the platform 115 with the tooth form 422, the platform 115 is smoothly transformed into the form of the solid line \hat{2}.

In the meantime, the support roller 430 is installed in the bottom side of the extruded product 401, which corresponds to the star roller 420 to support the load applied from the star roller 420.

Particularly, in the support roller 430, the groove 439 is built up so that the protrusion 109 be inserted. The groove 439 is formed on the circumference of the support roller 430.

Particularly, the support roller 430 located in the inner side of the bent portion 102 of the extruded product 401 guides the moving direction of the extruded product 401 to be a straight line, preventing the extruded product 401 from bending or being transformed.

In addition, a plurality of star roller 420 and a plurality of support roller 430 are provided in the moving direction of the extruded product 401 in order to process the extruded product 401.

The pairs of each star roller 420 and each support roller 430 process the extruded product 401 with multiple time to gradually increase the depth h of the lengthwise direction air channel 112. Thus, the difference between the widthwise direction air channel 110 and the lengthwise direction air channel 112 is minimized.

The star roller 420 and the support roller 430 rotates respectively in connection with the extrusion rate of the extruded product 401, preventing from being extended to the direction in which the extruded product 401 is ejected in the molding process of the extruded product 401.

Moreover, as to the extruded product 401, in the process of shaping, the number of rotation of the star roller 420 and the support roller 430 is adjusted in order to prevent the extruded product 401 from being bent to the star roller 420 or the support roller 430.

Accordingly, when the extruded product 401 is extruded from the extrusion die 410, the form of the both side ends are symmetrical, thus, it is prevented from being transformed to only one of the both side ends. The number of rotation is adjusted when it is operated by the star roller 420 and the support roller 430 thus, it is prevented from being bent to the star roller 420 or the support roller 430.

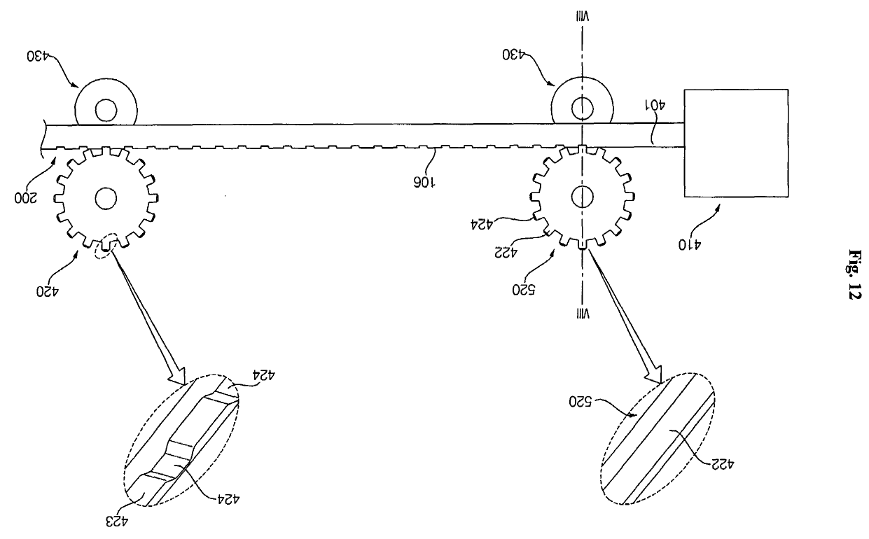

Hereinafter, the heat sink manufacturing method according to the present invention will be explained in detail with reference to FIG. 11.

FIG. 11 is a flow chart where the manufacturing method of a heat sink according to the present invention is illustrated.

As shown in FIG. 11, the heat sink 100 according to the present invention is comprised of an extrusion step S10 where the heated metal is extruded so that the widthwise direction air channel be formed, a rolling processing step S20 where the lengthwise direction air channel 112 is formed to intersect with the widthwise direction air channel of the extruded product 401 formed by the extrusion S10 through pressurizing the star roller 420 where the tooth form 422 is formed, a cutting processing step S30 manufacturing a pair of the heat sink 100 by cutting the extruded product 401 where the widthwise direction air channel 110 and the lengthwise direction air channel 112 are formed respectively after the rolling processing step S20 in the lengthwise direction, and a hole processing step S40 forming a hall 101 in the plate part 104 of the heat sink 100.

The extrusion step S10 is the step where a metal is extruded by the extrusion die 410, while the metal extruded from the extrusion die 410 forms the extruded product 401 in which the widthwise direction air channel 110 is manifoldly formed.

The rolling processing step S20 is the step where the lengthwise direction air channel 112 is formed in the barrier 115 of the extruded product 401 through the star roller 420 and the support roller 430. It is preferable that the rolling processing step S20 is performed with a multiple step in order to suppress that the excessive deformation is generated in the extruded product 401.

The cutting processing step S30 is the step where a pair heat sink 200 where the the both side ends are formed to be symmetrical is cut in the lengthwise direction to obtain 2 heat sinks 100.

The hole processing step S40 is the step where the hall 101 is formed in the heat sink 100, while the hall 101 is used in the process of fixing the heat sink 100 to the module.

In this case, the hole processing step S40 may be carried out prior to the cutting processing step S30.

FIG. 12 is a side view in which a heat sink manufacturing apparatus according to a second embodiment of the present invention is illustrated.

As to the second embodiment according to the present invention, it is identical with the first embodiment except that the star roller is comprised as miltiple form in the first embodiment.

That is, in the star roller 520 of a first row which performs first rolling with the extruded product 401 extruded from the extrusion die 410, only the tooth form 422 is formed without the addition tooth 424 unlike the first embodiment. At the same time, the tooth form 422 is formed with the addition tooth form 424 like the first embodiment in the star roller 420 of the second row.

Therefore, the star roller 520 of the first row compresses the extruded product 401 to form only the lengthwise direction air channel 112, while the star roller 420 of the second row processes the platform 115 with a slow slope through the addition tooth form 424.

In addition, the star roller 420 of the second row makes the height of a teeth to be higher than tooth form 422 of the star roller of the first row 520 to deeply form the depth of the lengthwise direction air channel 112.

Further, a plurality of star rollers can be installed after the second row star roller 420.

Hereinafter, as to the other configurations according to the second embodiment, since it is identical with the first embodiment, the detailed description is omitted.

Hereinafter, referring to the figure, the preferred embodiment of the panel according to the present invention is circumstantially illustrated.

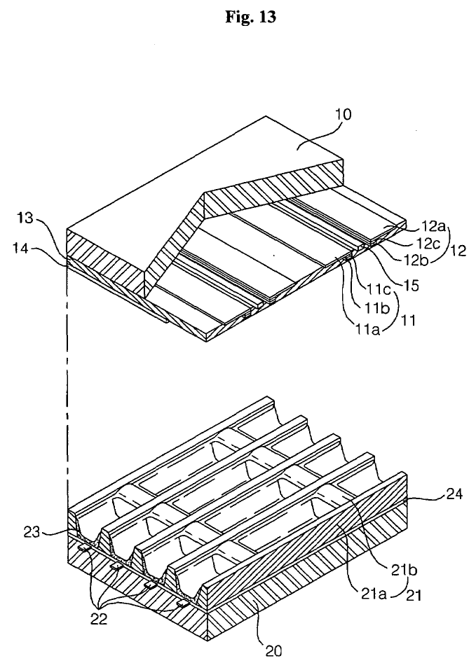

FIG. 13 is a perspective drawing in which the internal fabric of a plasma display panel according to the present invention is illustrated. As shown in FIG. 13, the plasma display panel includes a scan electrode 611 and a sustain electrode 612 that are a sustain electrode pair formed in the front substrate 610, and an address electrode 622 formed in the rear substrate 620.

Generally, the sustain electrode pairs 611, 612 include transparent electrode 611a, 612a and bus electrode 611b, 612b made of Indium-Tin-Oxide ITO. The bus electrode 611b, 612b can be formed with metal such as silver Ag, chrome Cr or the lamination of chrome/copper/chrome Cr/Cu/Cr or the lamination of the chrome/aluminium/chrome Cr/Al/Cr. Bus electrode 611b, 612b are formed on the transparent electrode 611a, 612a to play the role of reducing the voltage drop due to the transparent electrode 611a, 612a having high resistance.

In the meantime, according to the embodiment of the present invention, the sustain electrode pair 611, 612 is comprised of the bus electrodes 611b, 612b without the transparent electrode 611a, 612a as well as of the structure that the transparent electrode 611a, 612a and the bus electrodes 611b, 612b are laminated. Such structure does not use the transparent electrode 611a, 612a, therefore, the unit cost of the panel manufacture can be reduced. The bus electrode 611b, 612b used in such structure may use various material such as photosensitive Ag in addition to the material enumerated in the above.

Black Matrix BM 615 which prevents light to reduce a reflection by absorbing the external light generated in the outside of the upper plate 610 and improves the purity of the upper plate 610 and the contrast is arranged between the transparent electrode 611a, 612a of the scan electrode 611 and the sustain electrode 612 and the bus electrodes 611b, 611c.

The black matrix 15 according to the embodiment of the present invention is formed on the upper plate 10, while it may be comprised of a first black matrix 615 and a second black matrix 611c, 612c. The first black matrix 615 is formed in the location overlapped with the barrier rib 621, while the second black matrix 611c, 612c is formed between the transparent electrodes 611a, 612a and the bus electrode 611b, 612b. In this case, the first black matrix 615 and the second black matrix 611c, 612c which is called black layer or black electrode layer may be simultaneously formed in the forming process to be physically connected or may not be formed simultaneously not to be physically connected.

Further, in case it is physically connected, the first black matrix 615 and the second black matrix 611c, 612c are formed with the same material. However, in case it is physically separated, the first black matrix 615 and second black matrixess 611c, 612c can be formed with other material.

In the front substrate 610 where the scan electrode 611 and the sustain electrode 612 are formed side by side, an upper side dielectric layer 613 and a protective film 614 are laminated. Charged particles generated by discharge are accumulated in the upper side dielectric layer 613 which can perform protecting sustain electrode pairs 611, 612. The protective film 614 protects the upper side dielectric layer 613 from the sputtering of the charged particles generated in the gaseous discharge, enhancing the emission efficiency of the secondary electron. Moreover, in the protective film 614, magnesium oxide MgO is generally used or Si—MgO in which silicon Si is added can be used. The content of the silicon Si added to the protective film 614 ranges 50 PPM to 200 PPM on the base of the weight percent wt %.

In the meantime, the address electrode 622 is formed to intersect with the scan electrode 611 and the sustain electrode 612. Moreover, in the rear substrate 620 in which the address electrode 622 is formed, a lower dielectric layer 623 and a barrier rib 621 are formed.

In the surface of the barrier rib 621 and the lower dielectric layer 623, the fluorescent material layer is formed. As to the barrier rib 621, a column barrier rib 621a and a row barrier rib 621b are formed in a enclosed type, physically dividing the discharge cell, preventing the ultraviolet ray and the visible light generated by discharge from leaking out to the adjacent discharge cell.

In the embodiment of the present invention, various barrier rib 621 structures may be implemented as well as the structure of the barrier rib 621 shown in FIG. 13. For example, the various barrier rib 621 structures may include a differential type barrier rib structure where the height of the column barrier rib 621a and the row barrier rib 621b is different, a channel type barrier rib structure where a channel which can be used as a ventilating passage in one or more of the column barrier rib 621a and the row barrier rib 621b is formed, and a hollow type barrier rib structure where a hollow is formed in one or more of the column barrier rib 621a and the row barrier rib 621b.

In case of the differential type barrier rib structure, it is preferable that the height of the row barrier rib 621b is higher than the column barrier rib 621a, while, in case of the channel type barrier rib structure or the hollow type barrier rib structure, it is preferable that the channel or the hollow is formed in the row barrier rib 621b.

In the meantime, in the embodiment of the present invention, it is explained that each of the discharge cell R, G and B are arranged in the same line, however, the other shape of arrangement is possible. For example, the arrangement of the delta type where R, G and B discharge cells are arranged in a triangle form is possible. Further, the various polygonal shape of the discharge cell including a pentagon, a hexagon as well as a square shape can be implemented.

Moreover, the fluorescent material layer performs light-emitting due to ultraviolet ray generated in the gaseous discharge and generates one of visible light Red R, Green G and Blue B. In the discharge space provided between the front/rear 610, 620 substrate and the barrier rib 621, an inert mixing gas such as He+Xe, Ne+Xe, He+Ne+Xe is injected for discharge.

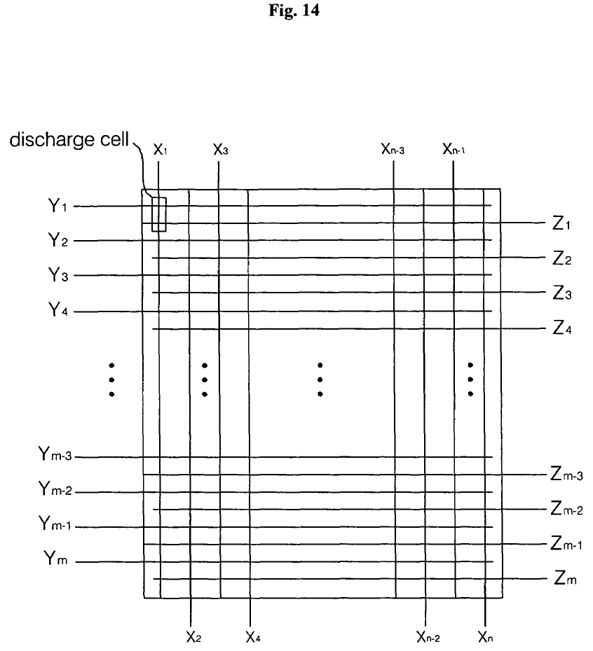

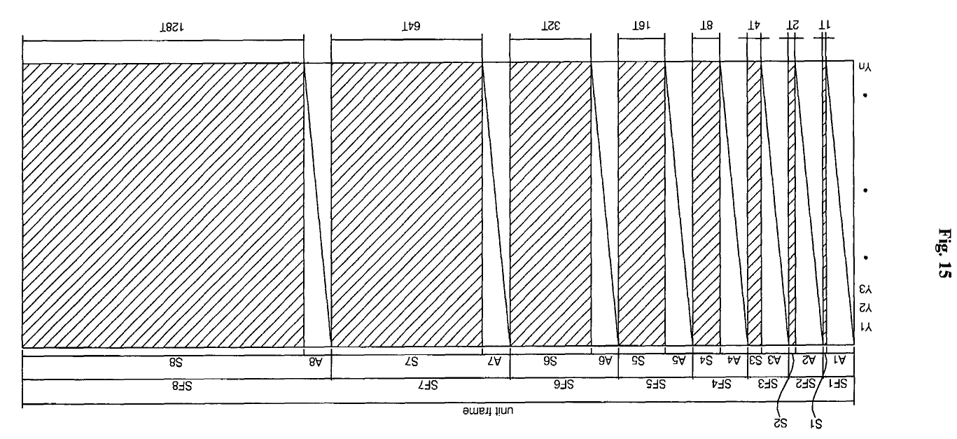

FIG. 14 shows an embodiment of electrode arrangement of the plasma display panel. As shown in FIG. 2, it is preferable that a plurality of discharge cells comprising the plasma display panel are arranged as matrix type. The plurality of discharge cells are provided in the intersection of the scan electrode line Y1 to Ym, the sustain electrode line Z1 to Zm, and the address electrode line X1 to Xm. The scan electrode line Y1 to Ym may be drived sequentially or simultaneously, while the sustain electrode line Z1 to Zm may be drived simultaneously. The address electrode line X1 to Xm may be divided into odd number lines and even number lines for driving or sequentially drived.

The electrode arrangement shown in FIG. 14 is just an embodiment of the electrode arrangement of the plasma panel according to the present invention. Therefore, the present invention is not restricted in the electrode arrangement and the driving method of the plasma display panel shown in FIG. 2. For example, the dual scan mode where two scan electrode lines among the scan electrode lines Y1 to Ym are simultaneously scanned is available. Further, in the center area of the panel, the address electrode line X1 to Xn may be divided into the upper/lower part for driving.

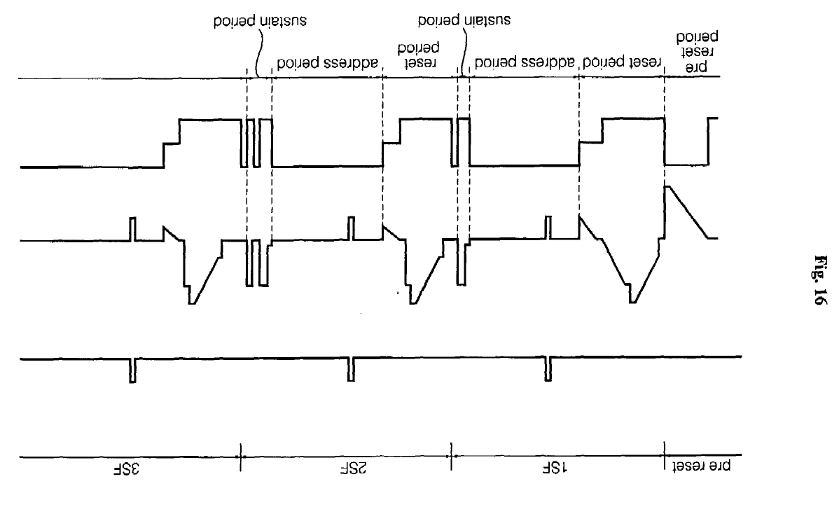

FIG. 15 is a timing diagram of the time divided driving method according to an embodiment in which one frame is time-divided into a plurality of subfields. The unit frame can be divided into a predetermined number, for example, 8 subfields SF1, . . . ,SF8 in order to implement a time-devided gray scale. Further, each subfield SF1, . . . ,SF8 is divided into a reset period(not shown), an address period A1, . . . , A8, and a sustain period S1, . . . , S8.

According to the embodiment of the present invention, the reset period can be omitted in at least one subfield among a plurality of subfields. For example, the reset period may be existed only in the first subfield, or may be existed only in the middle subfield between the first subfield and the total subfield.

In each address period A1, . . . , A8, a display data signal is applied to the address electrode X, while the scan pulse corresponding to each scan electrode Y is sequentially applied.

In each sustain period S1, . . . ,S8, the sustain pulse is alternately applied to the scan electrode Y and the sustain electrode Z, so that the sustain discharge is generated in the discharge cells in which wall charges are formed in the address period A1, . . . , A8.

The luminance of the plasma display panel is proportional to the number of sustain discharge pulse in the sustain discharge period S1, . . . , S8 occupied in the unit frame. In case that one frame forming one image is expressed with 8 subfields and 256 gray scale, the number of the different sustain pulse can be sequentially allocated in each subfield in the rate of 1, 2, 4, 8, 16, 32, 64, 128. In order to obtain the luminance of 133 gray scale, it is necessary to address cells during subfield 1 section, subfield 3 section and subfield 8 section for sustain discharging.

According to the weight of the subfields due to Automatic Power Control APC step, the sustain discharge number allocated to each subfield can be variably determined. That is, as described above, a frame is divided into 8 subfields, however, the present invention is not restricted in such a case, but the number of the subfield forming a frame can be variously changed according to a design type. For example, a frame can be divided into 8 subfields or more such as 12 subfields or 16 subfield to drive the plasma display panel.

Further, it is possible that the sustain discharge number allocated to each subfield can be variously changed in consideration of gamma characteristics or panel characteristics. For example, the gray scale level allocated to the subfield 4 can be lowered from 8 to 6, while the gray scale level allocated to the subfield 6 can be enhanced from 32 to 34.

FIG. 16 shows a timing diagram of a first embodiment on driving signals for driving a plasma display panel in one subfield divided as described in the above.

The subfield comprises a pre reset period for forming positive wall charges on the scan electrodes Y and forming negative wall charges on the sustain electrode Z, a reset period for initializing the discharge cells of the whole screen by using the wall charge distribution formed due to the pre reset period, an address period for selecting the discharge cell, and a sustain period for maintaining the discharge of the selected discharge cells.

The reset period is comprised of a set down period and a setup period. In the setup period, a ramp-up waveform is simultaneously applied to all the scan electrodes to generate a microdischarge in all the discharge cells. Accordingly, the wall charge is generated. In the setdown period, a ramp-down waveform descending from the positive polarity voltage lower than the peak voltage of the ramp-up waveform is applied to all the scan electrodes Y to generate an erase discharge in all the discharge cells. Accordingly, wall charges generated by the set up discharge and dispensable charges among space charges are erased.

In the address period, a scan signal of negative polarity is sequentially applied to the scan electrode, while the data signal of positive polarity is simultaneously applied to the address electrode X. The address discharge is a generated due to the voltage difference of the scan signal and the data signal and to the wall voltage created during the reset period to select a cell. In the meantime, during the set down period and the address period, a signal maintaining the sustain voltage is applied to the sustain electrode.

In the sustain period, the sustain pulse is alternately applied to the scan electrode and the sustain electrode to generate the sustain discharge between the scan electrode and the sustain electrode as a surface discharge form.

The drive waveforms shown in FIG. 16 is a first embodiment of signals for driving the plasma display panel according to the present invention, while the present invention is not restricted in FIG. 16. For example, the pre reset period can be omitted, and the polarity and the voltage level of the driving signals shown in FIG. 16 are changeable according to a need, while it is possible that an erase signal for erasing the wall charge after the sustain discharge is completed can be applied to the sustain electrode. Moreover, a single sustain driving where the sustain signal is applied to only one of the scan electrode Y and the sustain electrode Z to generate a sustain discharge.

As described in the above, the present invention was illustrated with reference to the exemplified drawings. However, the present invention is not restricted to the embodiment and the drawing filled in the specification, while an application may be implemented within the range in which the technical spirit of the present invention is protected by the person skilled in the art.

As to the heat sink manufacturing method of the plasma display apparatus and the manufacturing device according to the present invention as described in the above, the widthwise direction air channel and the lengthwise direction air channel are formed due to the extrusion and the rolling processing to facilitate the processing, in addition, the extrusion and the rolling processing are consecutively performed so that it has an effect that the productivity is improved much more than before.

Further, as to the heat sink manufacturing method of the plasma display apparatus according to the present invention and the manufacturing device, since the lengthwise direction air channel is formed into the direction different with the eject direction through the star roller although the heat sink is manufactured by the extrusion, it has the effect that the manufacturing method is simplified.

Further, as to the heat sink manufacturing method of the plasma display apparatus according to the present invention and the manufacturing device, since the extrusion die or the star roller continuously processes the extruded product is used, which can be cut to use in the various length according to the size of the plasma display apparatus.

Further, as to the heat sink manufacturing method of the plasma display apparatus according to the present invention and the manufacturing device, it has the effect that the smoothness and the flatness are more precisely formed because of making the heat sink through the extrusion and the rolling processing.

Further, as to the heat sink manufacturing method of the plasma display apparatus according to the present invention and the manufacturing device, since the heat sink is processed through the extrusion by the extrusion die, the cost of manufacturing the extrusion die is much more inexpensive in comparision with diecasting or the other press processing. In addition, the damage of the extrusion die in manufacturing is remarkably less, thus, it has the effect that a durability is high.

Further, as to the heat sink manufacturing method of the plasma display apparatus according to the present invention and the manufacturing device, since the difference between the widthwise direction air channel and the lengthwise direction air channel is minimized through the additional tooth form formed in the star roller, it has the effect that the flow of the air by the heat sink is more smooth.

Further, as to the heat sink of the plasma display apparatus according to the present invention, since it is manufactured as pair heat sink form in which the both side ends are symmetrical, when being extruded in the extrusion die, it is prevented from being bending to one side or being transformed.

Further, as to the heat sink of the plasma display apparatus according to the present invention, since the platform of the widthwise direction air channel formed by the extrusion and the lengthwise direction air channel formed by the rolling processing is pressurized by the addition tooth form to be smoothly connected, it has the effect that the flow of the convected air is more smoothly moved than the adjacent air channel.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A heat sink of a plasma display apparatus, the heat sink comprising:
a plurality of radiators formed to be protruded through an extrusion by an extrusion die and a rolling processing pressurized by a star roller; and
a plate part in which a widthwise direction air channel and a lengthwise direction air channel are formed by the plurality of protruded radiators.

2. The heat sink as claimed in claim 1,
further comprising a bent portion protruded to the opposite direction to the protrusion direction of the radiator in the plate part.

3. The heat sink as claimed in claim 2,
further comprising a plateau formed flat between the bent portion and the radiator interval in the plate part.

4. The heat sink as claimed in claim 2,
wherein the bent portion is formed in the both side ends of the plate part respectively.

5. The heat sink as claimed in claim 4,
wherein the heat sink is manufactured as a pair heat sink form in which a pair is combined, while the pair heat sink is cut and separated to at least one of the widthwise direction and the lengthwise direction.

6. The heat sink as claimed in claim 1,
wherein the heat sink is formed to at least one of the widthwise direction and the lengthwise direction to be symmetrical.

7. The heat sink as claimed in claim 1,
wherein the heat sink is manufactured as a pair heat sink form in which a pair is combined, while the pair heat sink is cut and separated to at least one of the widthwise direction and the lengthwise direction.

8. The heat sink as claimed in claim 1,
further comprising a heat transfer member installation unit in which the heat transfer member is settled with a hollow type in the opposite surface in which the radiator is formed in the plate part.

9. The heat sink as claimed in claim 8,
wherein, in the widthwise direction air channel and the lengthwise direction air channel of the heat sink, one is formed by the extrusion, while the other is formed by the rolling processing.

10. The heat sink as claimed in claim 8,
wherein, in the plate part, the bent portion and the radiator include a plateau formed flat, while the heat transfer member installation unit is formed in the opposite surface of the plateau.

11. The heat sink as claimed in claim 1,
wherein, in the widthwise direction air channel and the lengthwise direction air channel of the heat sink, one is formed by the extrusion, while the other is formed by the rolling processing.

12. The heat sink as claimed in claim 1,
wherein the widthwise direction air channel and the lengthwise direction air channel form a platform where a height is different.

13. The heat sink as claimed in claim 1,
wherein the widthwise direction air channel and the lengthwise direction air channel form a platform where a height is different, while the platform is formed to be inclined.

14. The heat sink as claimed in claim 1,
wherein the widthwise direction air channel and the lengthwise direction air channel form a platform where a height is different, while the platform is formed to be curved surface.

15. A plasma display apparatus comprising:
a plate part in which one of a widthwise direction air channel and a lengthwise direction air channel is formed through an extrusion by an extrusion die; and
a heat sink in which a protrusion is formed through a rolling processing by a star roller pressurizing the plate part with protruding the other of the widthwise direction air channel and the lengthwise direction air channel in the plate part.

16. The plasma display apparatus as claimed in claim 15,
wherein the widthwise direction air channel and the lengthwise direction air channel form a platform where a height is different,.

17. The plasma display apparatus as claimed in claim 15,
wherein the heat sink is manufactured as a pair heat sink form, while the pair heat sink is cut and separated to at least one of the widthwise direction and the lengthwise direction.

18. The plasma display apparatus as claimed in claim 15,
wherein, in the widthwise direction air channel and the lengthwise direction air channel of the heat sink, one is formed by the extrusion, while the other is formed by the rolling processing.

19. The plasma display apparatus as claimed in claim 15,
wherein the widthwise direction air channel and the lengthwise direction air channel form a platform where a height is different.
